(19) United States
(12) Patent Application Publication
(10) Pub. No.: US 2026/0190624 A1
(43) Pub. Date: Jul. 2, 2026

(54) DISPLAY DEVICE INCLUDING SHIELDING CAPACITOR

(71) Applicant: LG Display Co., Ltd., Seoul (KR)

(72) Inventors: Chul-Woo IM, Paju-si (KR); Moung-O KIM, Paju-si (KR); Jin-Woo PARK, Paju-si (KR); Man-Ki JI, Paju-si (KR)

(73) Assignee: LG Display Co., Ltd., Seoul (KR)

(21) Appl. No.: 19/376,861

(22) Filed: Oct. 31, 2025

(30) Foreign Application Priority Data
Dec. 26, 2024 (KR) 10-2024-0196991

(51) Int. Cl. H10K 59/121; H10K 59/131

(52) U.S. Cl. CPC H10K 59/1213; H10K 59/131

(57) ABSTRACT

A display device includes: a display panel including a display area having a plurality of subpixels and a non-display area at a periphery of the display area; a storage capacitor and a first transistor in each of the plurality of subpixels; a data line disposed adjacent to a gate electrode of the first transistor; and a shielding capacitor disposed to overlap the data line, wherein a first width of the shielding capacitor is greater than a second width of the gate electrode of the first transistor.

### CROSS-REFERENCE TO RELATED APPLICATION

The present application claims the priority of Republic of Korea Patent Application No. 10-2024-0196991, filed on Dec. 26, 2024, which is hereby incorporated by reference in its entirety.

### BACKGROUND

### Field of the Disclosure

The present disclosure relates to a display device, and more particularly to a display device including a shielding capacitor.

### Description of the Background

Recently, various flat panel display devices such as a liquid crystal display (LCD) device, an organic light emitting diode (OLED) display device, and a field emission display (FED) device having excellent properties of a thin profile, a light weight, and a low power consumption have been developed and applied to various fields.

Among the various flat panel display devices, an organic light emitting diode (OLED) display device is an emissive type device that does not include a backlight unit used in a non-emissive type device, such as a liquid crystal display (LCD) device. As a result, the OLED display device has advantages in a viewing angle, a contrast ratio, and a power consumption to be applied to various fields.

The OLED display device includes a pixel circuit in each subpixel, and the pixel circuit includes a storage capacitor for driving a light emitting diode. In the OLED display device, a voltage of a gate electrode of a driving transistor may be changed due to a coupling between the gate electrode of the driving transistor and a data line to cause deterioration such as a vertical crosstalk.

### SUMMARY

Accordingly, the present disclosure is directed to a display device that substantially obviates one or more of the problems due to limitations and disadvantages of the related art.

More specifically, the present disclosure is to provide a display device where a voltage change of a gate electrode of a driving transistor is minimized or reduced, and deterioration such as a vertical crosstalk is prevented or suppressed by forming a shielding capacitor between a data line and a shielding pattern under the data line corresponding to the gate electrode of the driving transistor.

Further, the present disclosure is to provide a display device where a coupling between a gate electrode of a driving transistor and a data line is minimized or reduced, and deterioration such as a vertical crosstalk is prevented or suppressed by forming a shielding pattern under the data line to have a width greater than a width of the gate electrode of the driving transistor.

Additional features and advantages of the disclosure will be set forth in the description which follows, and in part will be apparent from the description, or may be learned by practice of the disclosure. These and other advantages of the disclosure will be realized and attained by the structure particularly pointed out in the written description and claims hereof as well as the appended drawings.

To achieve these and other advantages and in accordance with the purpose of the present disclosure, as embodied and broadly described herein, a display device includes: a display panel including a display area having a plurality of subpixels and a non-display area at a periphery of the display area; a storage capacitor and a first transistor in each of the plurality of subpixels; a data line disposed adjacent to a gate electrode of the first transistor; and a shielding capacitor disposed to overlap the data line, wherein a first width of the shielding capacitor is greater than a second width of the gate electrode of the first transistor.

It is to be understood that both the foregoing general description and the following detailed description are explanatory and are intended to provide further explanation of the disclosure as claimed.

### BRIEF DESCRIPTION OF THE DRAWINGS

The accompanying drawings, which are included to provide a further understanding of the present disclosure and are incorporated in and constitute a part of this specification, illustrate example embodiments of the present disclosure and together with the description serve to explain various principles of the disclosure. In the drawings:

FIG. 1 is a view showing a display device according to a first example embodiment of the present disclosure;

FIG. 2 is a circuit diagram showing a subpixel of a display device according to a first example embodiment of the present disclosure;

FIG. 3 is a plan view showing first, second, and third subpixels of a display device according to a first example embodiment of the present disclosure;

FIG. 4 is a cross-sectional view taken along a line IV-IV′ in FIG. 3;

FIG. 5 is a plan view showing first, second, and third subpixels of a display device according to a second example embodiment of the present disclosure;

FIG. 6 is a cross-sectional view taken along a line VI-VI′ in FIG. 5;

FIG. 7 is a circuit diagram showing a subpixel of a display device according to a third example embodiment of the present disclosure;

FIG. 8 is a plan view showing first, second, and third subpixels of a display device according to a third example embodiment of the present disclosure; and

FIG. 9 is a cross-sectional view taken along a line IX-IX′ in FIG. 8.

### DETAILED DESCRIPTION

Advantages and features of the present disclosure, and implementation methods thereof will be clarified through following example aspects described with reference to the accompanying drawings. The present disclosure may, however, be embodied in different forms and should not be construed as limited to the example aspects set forth herein. Rather, these example aspects are provided so that this disclosure may be sufficiently thorough and complete to assist those skilled in the art to fully understand the scope of the present disclosure. Further, the protected scope of the present disclosure may be defined by scopes of claims and their equivalents.

The shapes, sizes, ratios, angles, numbers, and the like, which are illustrated in the drawings to describe various example aspects of the present disclosure, are merely given by way of example. Therefore, the present disclosure is not limited to the illustrations in the drawings. Like reference numerals refer to like elements throughout the specification, unless otherwise specified.

In the following description, where the detailed description of the relevant known function or configuration may unnecessarily obscure a feature or aspect of the present disclosure, a detailed description of such known function or configuration may be omitted or a brief description may be provided.

Where the terms “comprise,” “have,” “include,” and the like are used, one or more other elements may be added unless a more specific term, such as “only,” is used. An element described in the singular form is intended to include a plurality of elements, and vice versa, unless the context clearly indicates otherwise.

In construing an element, the element is to be construed as including an error or a tolerance range even where no explicit description of such an error or tolerance range is provided.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly),” is used. For example, where an element or layer is disposed “on” another element or layer, a third layer or element may be interposed therebetween.

Although the terms “first,” “second,” A, B, (a), (b), and the like may be used herein to refer to various elements, these elements should not be interpreted to be limited by these terms as they are not used to define a particular order or precedence. These terms are only used to refer to one element separately from another. For example, a first element could be termed a second element, and, similarly, a second element could be termed a first element, without departing from the scope of the present disclosure.

The term “at least one” should be understood to include all combinations of one or more of related elements. For example, the term “at least one of first, second, and third elements” may include all combinations of two or more of the first, second, and third elements, as well as the first, second, or third element individually.

The term “display device” may include a display device in a narrow sense such as liquid crystal module (LCM), an organic light emitting diode (OLED) module, and a quantum dot (QD) module including a display panel and a driving unit for driving the display panel. In addition, the term “display device” may include a complete product (or a final product) including the LCM, the OLED module, or the QD module, such as a notebook computer, a television, a computer monitor, an equipment display device including an automotive display apparatus or a display apparatus of an equipment other than a vehicle, and a set electronic apparatus or a set device (or a set apparatus) such as a mobile electronic apparatus of a smart phone or an electronic pad.

Accordingly, a display device of the present disclosure may include an applied product or a set device of a final user's device including the LCM, the OLED module, or the QD, module as well as a display device in a narrow sense such as the LCM, the OLED module, and the QD module.

According to circumstances, the LCM, the OLED module, or the QD module having a display panel and a driving unit may be expressed as “a display device”, and an electronic apparatus of a complete product including the LCM, the OLED module, or the QD module may be expressed as “a set device.” For example, a display device in a narrow sense may include a display panel of a liquid crystal, an organic light emitting diode, or a quantum dot and a source printed circuit board (PCB) of a control unit for driving the display panel, and a set device may further include a set PCB of a set control unit electrically connected to the source PCB for controlling the entire set device.

The display panel of the present disclosure may include all kinds of display panels, such as a liquid crystal display panel, an organic light emitting diode display panel, a quantum dot display panel, and an electroluminescent display panel. The display panel of the present disclosure is not limited to a specific display panel of a bezel bending having a flexible substrate for an organic light emitting diode display panel and a lower back plate supporter. A shape or a size of the display panel for the display device of the present disclosure is not limited thereto.

For example, where the display panel is an organic light emitting diode display panel, the display panel may include a plurality of gate lines, a plurality of data lines, and a subpixel in a crossing region of the plurality of gate lines and the plurality of data lines. The display panel may include an array having a thin film transistor of an element for selectively applying a voltage to each subpixel, an emitting element layer on the array, and an encapsulating substrate or an encapsulation part covering the emitting element layer. The encapsulation part may protect the thin film transistor and the emitting element layer from an external impact and may prevent or at least reduce penetration of a moisture or oxygen into the emitting element layer. In addition, the emitting element layer on the array may include an inorganic light emitting layer, for example, a nano-sized material layer, or a quantum dot.

The thin film transistor of the present disclosure may include one of an oxide thin film transistor, an amorphous silicon thin film transistor, and a low temperature polycrystalline silicon thin film transistor.

Features of various embodiments of the present disclosure may be partially or entirely coupled to or combined with each other. They may be linked and operated technically in various ways as those skilled in the art may sufficiently understand. The aspects may be carried out independently of or in association with each other in various combinations.

Hereinafter, a display device according to various example embodiments of the present disclosure where an influence on an oxide semiconductor layer of a thin film transistor of a driving element part can be reduced by shielding a light emitted and transmitted from a subpixel and/or a light inputted from an exterior will be described in detail with reference to the accompanying drawings.

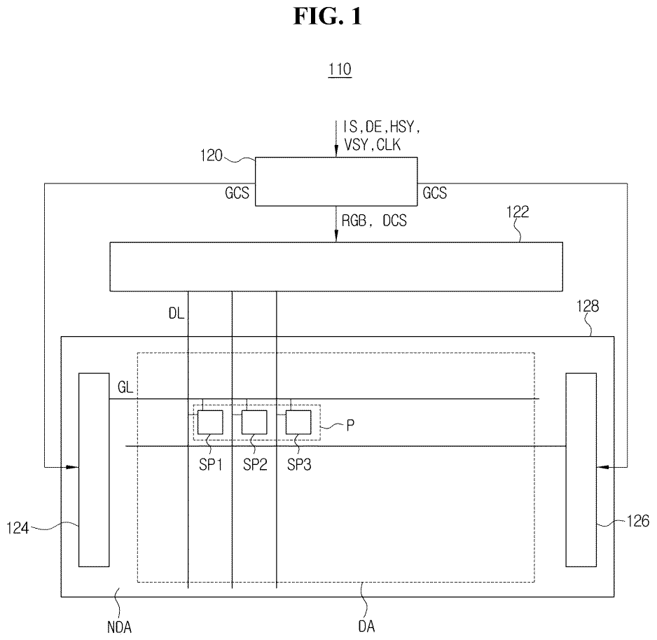

FIG. 1 is a view showing a display device according to a first example embodiment of the present disclosure. Although the display device may be an organic light emitting diode (OLED) display device, it is not limited thereto. For example, the display device may be a quantum dot display device, a micro light emitting diode (LED) display device, or a mini light emitting diode (LED) display device.

In FIG. 1, a display device 110 according to a first example embodiment of the present disclosure includes a timing controlling unit 120 (e.g., a circuit), a data driving unit 122 (e.g., a circuit), first and second gate driving units 124 and 126 (e.g., circuits), and a display panel 128.

The timing controlling unit 120 generates an image data RGB, a data control signal DCS, and a gate control signal GCS using an image signal IS and a plurality of timing signals including a data enable signal DE, a horizontal synchronization signal HSY, a vertical synchronization signal VSY, and a clock signal CLK transmitted from an external system such as a graphic card or a television system.

The timing controlling unit 120 transmits the image data RGB and the data control signal DCS to the data driving unit 122 and transmits the gate control signal GCS to the first and second gate driving units 124 and 126.

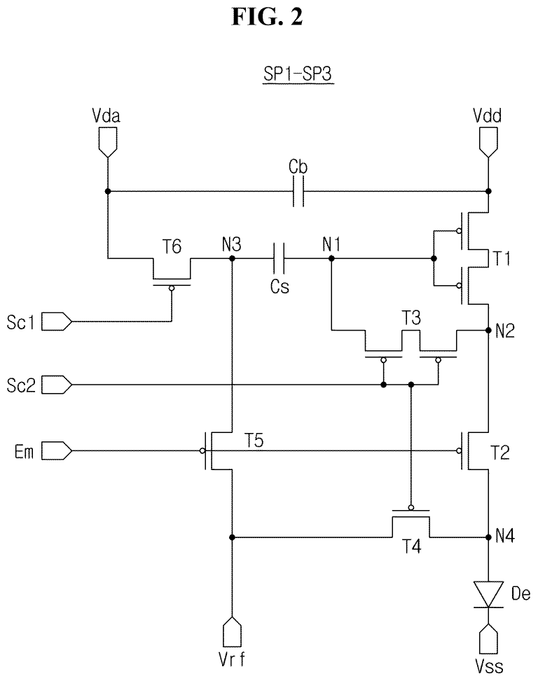

The data driving unit 122 generates a data signal (data voltage) Vda (of FIG. 2) using the image data RGB and the data control signal DCS transmitted from the timing controlling unit 120 and applies the data signal Vda to a data line DL of the display panel 128.

The first and second gate driving units 124 and 126 generate a gate signal (gate voltage) Sc1, Sc2 and Em (of FIG. 2) using the gate control signal GCS transmitted from the timing controlling unit 120 and applies the gate signals Sc1, Sc2, and Em to a gate line GL of the display panel 128.

The first and second gate driving units 124 and 126 may have a gate in panel (GIP) type to be formed in a non-display area NDA of a substrate of the display panel 128 having the gate line GL, the data line DL, and a pixel P.

Although the first and second gate driving units 124 and 126 are disposed in both side portions of the display panel 128 in the first example embodiment of FIG. 1, only one gate driving unit may be disposed in another embodiment, wherein this gate driving unit may be disposed in one side portion of the display panel 128.

The display panel 128 includes a display area DA at a central portion thereof and a non-display area NDA surrounding the display area DA. The display panel 128 displays an image using the gate signals Sc1, Sc2, and Em and the data signal Vda. For displaying an image, the display panel 128 includes a plurality of pixels P, a plurality of gate lines GL, and a plurality of data lines DL in the display area DA.

Each of the plurality of pixels P includes first, second, and third subpixels SP1, SP2 and SP3. The gate line GL and the data line DL cross each other to define the first, second, and third subpixels SP1, SP2, and SP3, and each of the first, second, and third subpixels SP1, SP2, and SP3 is connected to the gate line GL and the data line DL.

For example, the first, second, and third subpixels SP1, SP2, and SP3 may correspond to red, green, and blue colors, respectively.

Although one pixel P exemplarily includes the first, second, and third subpixels SP1, SP2, and SP3 in the first example embodiment of FIG. 1, one pixel P may include first, second, and third subpixels SP1, SP2, and SP3 and a fourth subpixel not shown corresponding to red, green, blue, and white colors, respectively, in another embodiment.

When the display device 110 is an organic light emitting diode (OLED) display device, each of the first, second, and third subpixels SP1, SP2, and SP3 may include a plurality of transistors such as a switching transistor T6 (of FIG. 2) and a driving transistor T1 (of FIG. 2), a storage capacitor Cs (of FIG. 2), a shielding capacitor Cb (of FIG. 2), and a light emitting diode De (of FIG. 2).

FIG. 2 is a circuit diagram showing a subpixel of a display device according to a first example embodiment of the present disclosure.

In FIG. 2, each of the first, second, and third subpixels SP1, SP2, and SP3 of the display panel 128 of the display device 110 according to a first example embodiment of the present disclosure includes first to sixth transistors T1 to T6, a storage capacitor Cs, a shielding capacitor Cb, and a light emitting diode De.

Although each of the first, second, and third subpixels SP1, SP2, and SP3 has a 6T1C structure having six transistors and one capacitor in the first example embodiment of FIG. 2, one subpixel may have one of a 3T1C structure having three transistors and one capacitor, a 7T1C structure having seven transistors and one capacitor, and a 8T1C structure having eight transistors and one capacitor in another embodiment.

Although the first to sixth transistors T1 to T6 have a positive type (i.e., a p-type transistor) in the first example embodiment of FIG. 2, at least one of the first to sixth transistors T1 to T6 may have a negative type (i.e., an n-type transistor) in another embodiment.

At least one of the first to sixth transistors T1 to T6 may be an oxide semiconductor thin film transistor, and the others of the first to sixth transistors T1 to T6 may be a low temperature polycrystalline silicon thin film transistor.

The first transistor T1 as a driving transistor is switched according to a voltage of a first node N1. A gate electrode of the first transistor T1 is connected to the first node N1, a source electrode of the first transistor T1 is connected to a high level signal (high level voltage) Vdd, and a drain electrode of the first transistor T1 is connected to a second node N2.

Although the first transistor T1 is illustrated, as an example, as having a dual gate type including two gate electrodes and two channel regions separated from each other in a plan view in the first example embodiment of FIG. 2, the first transistor T1 may have a single gate type including one gate electrode and one channel region in another embodiment.

The second transistor T2 as an emitting transistor is switched according to an emission signal Em. A gate electrode of the second transistor T2 is connected to the emission signal Em, a source electrode of the second transistor T2 is connected to the second node N2, and a drain electrode of the second transistor T2 is connected to a fourth node N4.

The third transistor T3 as a sensing transistor is switched according to a scan2 signal Sc2. A gate electrode of the third transistor T3 is connected to the scan2 signal Sc2, a source electrode of the third transistor T3 is connected to the second node N2, and a drain electrode of the third transistor T3 is connected to the first node N1.

Although the third transistor T3 is illustrated, as an example, as having a dual gate type including two gate electrodes and two channel regions separated from each other in a plan view in the first embodiment of FIG. 2, the third transistor T3 may have a single gate type including one gate electrode and one channel region.

The fourth transistor T4 is switched according to the scan2 signal Sc2. A gate electrode of the fourth transistor T4 is connected to the scan2 signal Sc2, a source electrode of the fourth transistor T4 is connected to the fourth node N4, and a drain electrode of the fourth transistor T4 is connected to a reference signal (reference voltage) Vrf.

The fifth transistor T5 is switched according to the emission signal Em. A gate electrode of the fifth transistor T5 is connected to the emission signal Em, a source electrode of the fifth transistor T5 is connected to the third node N3, and a drain electrode of the fifth transistor T5 is connected to the reference signal Vrf.

The sixth transistor T6 as a switching transistor is switched according to a scan1 signal Sc1. A gate electrode of the sixth transistor T6 is connected to the scan1 signal Sc1, a source electrode of the sixth transistor T6 is connected to the third node N3, and a drain electrode of the sixth transistor T6 is connected to a data signal Vda.

The storage capacitor Cs stores the data signal Vda and a threshold voltage (Vth) of the first transistor T1. A first capacitor electrode of the storage capacitor Cs is connected to the first node N1, and a second capacitor electrode of the storage capacitor Cs is connected to the third node N3.

The shielding capacitor Cb reduces a coupling between the data line DL and the first node N1. A first capacitor electrode of the shielding capacitor Cb is connected to the high level signal Vdd, and a second capacitor electrode of the shielding capacitor Cb is connected to the data signal Vda.

The light emitting diode De is connected between the fourth node N4 and a low level signal (low level voltage) Vss and emits a light of a luminance proportional to a current of the first transistor T1. An anode of the light emitting diode De is connected to the fourth node N4, and a cathode of the light emitting diode De is connected to the low level signal Vss.

The gate electrode of the first transistor T1, the first capacitor electrode of the storage capacitor Cs, and the drain electrode of the third transistor T3 constitute the first node N1, and the drain electrode of the first transistor T1, the source electrode of the second transistor T2, and the source electrode of the third transistor T3 constitute the second node N2. The second capacitor electrode of the storage capacitor Cs, the source electrode of the fifth transistor T5, and the source electrode of the sixth transistor T6 constitute the third node N3, and the drain electrode of the second transistor T2, the source electrode of the fourth transistor T4, and the anode of the light emitting diode De constitute the fourth node N4.

Each of the first, second, and third subpixels SP1, SP2, and SP3 of the display device 110 according to a first example embodiment of the present disclosure is driven through an initializing period, a sampling period, a holding period, and an emitting period.

During the initializing period, the second, third, fourth, and fifth transistors T2, T3, T4, and T5 are turned on due to the scan2 signal Sc2 and the emission signal Em of a logic low voltage, and the sixth transistor T6 is turned off due to the scan1 signal Sc1 of a logic high voltage. Since the reference signal Vrf is applied to the first, second, third, and fourth nodes N1, N2, N3, and N4, the first transistor T1 is turned off, and the first and second capacitor electrodes of the storage capacitor Cs, the gate electrode of the first transistor T1, and the anode of the light emitting diode De are initialized by the reference signal Vrf.

During the sampling period, the third, fourth, and sixth transistors T3, T4, and T6 are turned on due to the scan1 signal Sc1 and the scan2 signal Sc2 of a logic low voltage, and the second and fifth transistor T2 and T5 are turned off due to the emission signal Em of a logic high voltage. Since data signal Vda is applied to the third node N3 and the reference signal Vrf is applied to the fourth node N4, the first transistor T1 is turned on, and the second capacitor electrode of the storage capacitor Cs has the data signal Vda. As a result, the first capacitor electrode of the storage capacitor Cs has a sum (Vdd+Vth) of the high level signal Vdd and the threshold voltage Vth. Accordingly, the threshold voltage Vth is stored in the storage capacitor Cs, and the anode of the light emitting diode De is kept as the reference signal Vrf.

During the holding period, the second, third, fourth, fifth, and sixth transistors T2, T3, T4, T5, and T6 are turned off due to the scan1 signal Sc1, the scan2 signal Sc2, and the emission signal Em of a logic high voltage. As a result, the second capacitor electrode of the storage capacitor Cs is kept as the data signal Vda, and the first capacitor electrode of the storage capacitor Cs is kept as the sum (Vdd+Vth) of the high level signal Vdd and the threshold voltage Vth. Accordingly, the threshold voltage Vth is kept to be stored in the storage capacitor Cs, and the anode of the light emitting diode De is kept as the reference signal Vrf.

During the emitting period, the second and fifth transistors T2 and T5 are turned on due to the emission signal Em of a logic low voltage, and the third, fourth, and sixth transistors T3, T4, and T6 are turned off due to the scan1 signal Sc1 and the scan2 signal Sc2 of a logic high voltage. As a result, the reference signal Vrf is applied to the third node N3, and the voltage of the first node N1 becomes a sum (Vdd+Vth+Vrf−Vda) of a value (Vdd+Vth) obtained by adding a threshold voltage (Vth) to the high level signal Vdd and a value (Vrf−Vda) obtained by subtracting the data signal Vda from the reference signal Vrf. Accordingly, a current proportional to a square of a value ((Vth+Vrf−Vda)−Vth=Vrf−Vda) obtained by subtracting the threshold voltage (Vth) from a gate-source voltage (Vgs=(Vdd+Vth+Vrf−Vda)−Vdd=Vth+Vrf−Vda) flows through the first transistor T1, and the light emitting diode De emits a light of a luminance corresponding to the current flowing through the first transistor T1.

A plan structure and a cross-sectional structure of the first, second, and third subpixels SP1, SP2, and SP3 of the display device 110 will be illustrated with reference to drawings.

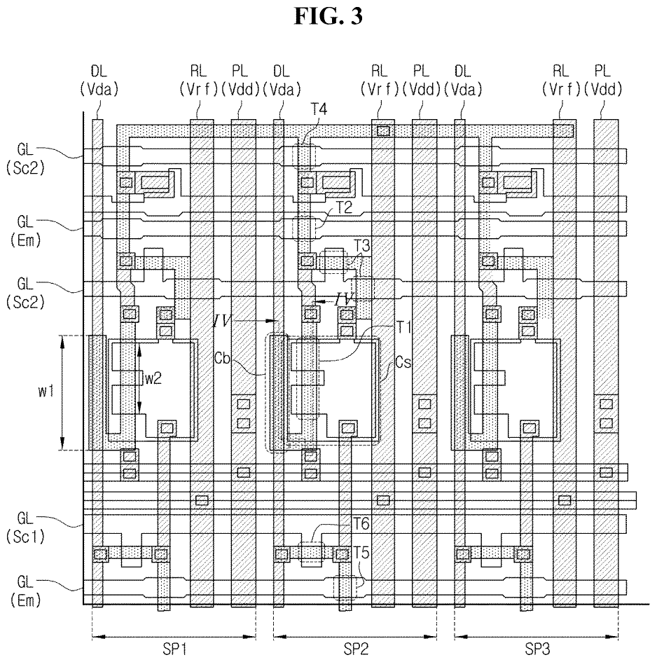

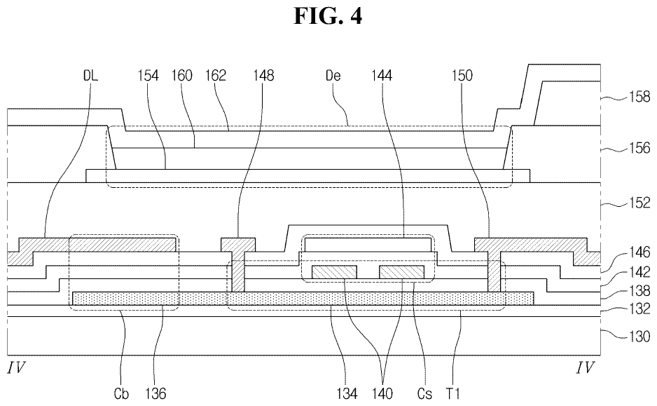

FIG. 3 is a plan view showing first, second, and third subpixels of a display device according to a first example embodiment of the present disclosure, and FIG. 4 is a cross-sectional view taken along a line IV-IV′ in FIG. 3.

In FIG. 3, each of the first, second, and third subpixels SP1, SP2, and SP3 of the display device 110 according to a first example embodiment of the present disclosure includes the gate lines GL, the data line DL, the reference line RL, and the power line PL. The gate line GL transmitting the scan2 signal Sc2, the gate line GL transmitting the emission signal Em, the gate line GL transmitting the scan2 signal Sc2, and the gate line GL transmitting the scan1 signal Sc1 are sequentially disposed along a horizontal direction. The data line DL transmitting the data signal Vda, the reference line RL transmitting the reference signal Vrf, and the power line PL transmitting the high level signal Vdd are sequentially disposed along a vertical direction.

The first transistor T1 is connected to the power line PL transmitting the high level signal, and the second transistor T2 is connected to the gate line GL transmitting the emission signal Em. The third transistor T3 is connected to the gate line GL transmitting the scan2 signal Sc2, and the fourth transistor T4 is connected to the gate line GL transmitting the scan2 signal Sc2 and the reference line RL transmitting the reference signal Vrf. The fifth transistor T5 is connected to the gate line GL transmitting the emission signal Em and the reference line RL transmitting the reference signal Vrf, and the sixth transistor T6 is connected to the gate line GL transmitting the scan1 signal Sc1 and the data line DL transmitting the data signal Vda.

A metal pattern 144 (of FIG. 4) is disposed on a gate electrode 140 (of FIG. 4) of the first transistor T1, and the gate electrode 140 of the first transistor T1 and the metal pattern 144 constitute the storage capacitor Cs.

A shielding pattern 136 (of FIG. 4) extending from a source region of a semiconductor layer 134 (of FIG. 4) of the first transistor T1 is disposed under the data line DL adjacent to the first transistor T1, and the shielding pattern 136 and the data line DL constitute the shielding capacitor Cb.

Since the shielding pattern 136 is disposed closer to the data line DL than the gate electrode 140 of the first transistor T1, most of electric field lines of the data line DL do not reach the gate electrode 140 of the first transistor T1 but reaches the shielding pattern 136. As a result, a coupling (or parasitic capacitance) between the data line DL and the gate electrode 140 (i.e., first node N1) of the first transistor T1 can be reduced, a voltage change of the gate electrode 140 of the first transistor T1 can be minimized or reduced, and deterioration such as a vertical crosstalk can be prevented or suppressed.

Accordingly, the shielding pattern 136 is formed to correspond to a whole of an end portion of the gate electrode 140 of the adjacent first transistor T1.

For example, a first width w1 of the shielding pattern 136 may be greater than a second width w2 of the gate electrode 140 of the first transistor T1.

In FIG. 4, a buffer layer 132 is disposed on an entire substrate 130, and a semiconductor layer 134 and a shielding pattern 136 are disposed on the buffer layer 132.

The buffer layer 132 blocks a moisture or an oxygen permeating from an exterior. For example, the buffer layer 132 may have a single layer or a multiple layer of an inorganic insulating material such as silicon oxide (SiO₂) and silicon nitride (SiNx).

The semiconductor layer 134 includes a channel region not doped with an impurity at a central portion thereof and source and drain regions doped with an impurity at both side portions of the channel region. For example, the semiconductor layer 134 may include a polycrystalline semiconductor material, such as polycrystalline silicon, or an oxide semiconductor material, such as indium gallium zinc oxide (IGZO), zinc oxide (ZnO), tin oxide (SnO₂), copper oxide (Cu₂O), nickel oxide (NiO), indium tin zinc oxide (ITZO), and indium aluminum zinc oxide (IAZO).

The shielding pattern 136 extends from the source region of the semiconductor layer 134 and is doped with an impurity. For example, the shielding pattern 136 may include a polycrystalline semiconductor material, such as polycrystalline silicon, or an oxide semiconductor material, such as indium gallium zinc oxide (IGZO), zinc oxide (ZnO), tin oxide (SnO₂), copper oxide (Cu₂O), nickel oxide (NiO), indium tin zinc oxide (ITZO), and indium aluminum zinc oxide (IAZO).

A gate insulating layer 138 is disposed on the semiconductor layer 134 and the shielding pattern 136 over the entire substrate 130, and a gate electrode 140 is disposed on the gate insulating layer 138 corresponding to the channel region of the semiconductor layer 134.

For example, the gate insulating layer 138 may have a single layer or a multiple layer of an inorganic insulating material, such as silicon oxide (SiO₂) and silicon nitride (SiNx).

For example, the gate electrode 140 may have a single layer or a multiple layer of a metallic material, such as molybdenum (Mo), aluminum (Al), chromium (Cr), gold (Au), titanium (Ti), nickel (Ni), neodymium (Nd), copper (Cu), and an alloy thereof.

The semiconductor layer 134, the gate insulating layer 138 and the gate electrode 140 constitute the first transistor T1.

Although the first transistor T1 exemplarily has a dual gate type including two gate electrodes and two channel regions separated from each other in a plan view in the first example embodiment of FIGS. 3 and 4, the first transistor T1 may have a single gate type including one gate electrode and one channel region in another embodiment.

A first interlayer insulating layer 142 is disposed on the gate electrode 140 over the entire substrate 130, and a metal pattern 144 is disposed on the first interlayer insulating layer 142 corresponding to the gate electrode 140.

For example, the first interlayer insulating layer 142 may have a single layer or a multiple layer of an inorganic insulating material, such as silicon oxide (SiO₂) and silicon nitride (SiNx).

For example, the metal pattern 144 may have a single layer or a multiple layer of a metallic material, such as molybdenum (Mo), aluminum (Al), chromium (Cr), gold (Au), titanium (Ti), nickel (Ni), neodymium (Nd), copper (Cu), and an alloy thereof.

The gate electrode 140, the first interlayer insulating layer 142 and the metal pattern 144 constitute the storage capacitor Cs, and the gate electrode 140 and the metal pattern 144 function as first and second capacitor electrodes, respectively, of the storage capacitor Cs.

A second interlayer insulating layer 146 is disposed on the metal pattern 144 over the entire substrate 130, and a source electrode 148, a drain electrode 150 and the data line DL are disposed on the second interlayer insulating layer 146.

For example, the second interlayer insulating layer 146 may have a single layer or a multiple layer of an inorganic insulating material, such as silicon oxide (SiO₂) and silicon nitride (SiNx).

The source electrode 148 and the drain electrode 150 are connected to the source region and the drain region, respectively, of the semiconductor layer 134 through contact holes in the second interlayer insulating layer 146, the first interlayer insulating layer 142, and the gate insulating layer 138.

The data line DL is disposed to overlap the shielding pattern 136.

For example, the source electrode 148, the drain electrode 150 and the data line DL may have a single layer or a multiple layer of a metallic material, such as molybdenum (Mo), aluminum (Al), chromium (Cr), gold (Au), titanium (Ti), nickel (Ni), neodymium (Nd), copper (Cu), and an alloy thereof.

The shielding pattern 136, the gate insulating layer 138, the first interlayer insulating layer 142, the second interlayer insulating layer 146, and the data line DL constitute the shielding capacitor Cb, and the shielding pattern 136 and the data line DL function as first and second capacitor electrodes, respectively, of the shielding capacitor Cb.

A planarizing layer 152 is disposed on the source electrode 148, the drain electrode 150 and the data line DL over the entire substrate 130, and a first electrode 154 is disposed on the planarizing layer 152.

For example, the planarizing layer 152 may have a single layer or a multiple layer of an organic insulating material, such as photoacryl and benzocyclobutene (BCB).

The first electrode 154 may be connected to a drain region of the second transistor T2 or a source region of the fourth transistor T4 through a contact hole in the planarizing layer 152.

For example, the first electrode 154 may be an anode and may have a single layer or a multiple layer of a transparent conductive material, such as indium tin oxide (ITO) and indium zinc oxide (IZO) or an opaque metallic material such as aluminum (Al), silver (Ag), copper (Cu), lead (Pb), molybdenum (Mo), titanium (Ti), and an alloy thereof.

A bank layer 156 is disposed on the first electrode 154, and a spacer 158 is disposed on the bank layer 156.

The bank layer 156 covers an edge portion of the first electrode 154 and has an opening exposing a central portion of the first electrode 154.

For example, the bank layer 156 may have a single layer or a multiple layer of an organic insulating material, such as photoacryl and benzocyclobutene (BCB).

For example, the spacer 158 may have a single layer or a multiple layer of an organic insulating material, such as photoacryl and benzocyclobutene (BCB).

An emitting layer 160 may be disposed on the first electrode 154 exposed through the opening of the bank layer 156, and a second electrode 162 is disposed on the emitting layer 160 over the entire substrate 130.

The emitting layer 160 may include a hole assisting layer such as a hole injecting layer and a hole transporting layer, an emitting material layer and an electron assisting layer such as an electron transporting layer and an electron injecting layer.

For example, the second electrode 162 may be a cathode and may have a single layer or a multiple layer of a transparent conductive material, such as indium tin oxide (ITO) and indium zinc oxide (IZO), or a half-transmissive material or an opaque metallic material, such as aluminum (Al), silver (Ag), copper (Cu), lead (Pb), magnesium (Mg), molybdenum (Mo), titanium (Ti), and an alloy thereof.

The first electrode 154, the emitting layer 160 and the second electrode 162 constitute the light emitting diode De.

Although not shown, an encapsulating layer may be disposed on the second electrode 162 over the entire substrate 130. For example, the encapsulating layer may include first and third encapsulating layers having a single layer or a multiple layer of an inorganic insulating material, such as silicon oxide (SiO₂) and silicon nitride (SiNx), and a second encapsulating layer between the first and third encapsulating layers and including an organic insulating material, such as acryl resin, epoxy resin, phenolic resin, polyamide resin, and polyimide resin.

A touch layer for sensing a touch may be disposed on the encapsulating layer.

In the display device 110 according to a first example embodiment of the present disclosure, the shielding pattern 136 extending from the source region of the semiconductor layer 134 of the first transistor T1 is disposed under the data line DL adjacent to the gate electrode 140 of the first transistor T1 to constitute the shielding capacitor Cb having the shielding pattern 136 and the data line DL. As a result, a coupling (or parasitic capacitance) between the data line DL and the gate electrode 140 of the first transistor T1 (between the data line DL and the first node N1) can be reduced, a voltage change of the gate electrode 140 of the first transistor T1 can be minimized or reduced, and deterioration such as a vertical crosstalk can be prevented or suppressed.

In another embodiment, the shielding pattern may be connected to the power line.

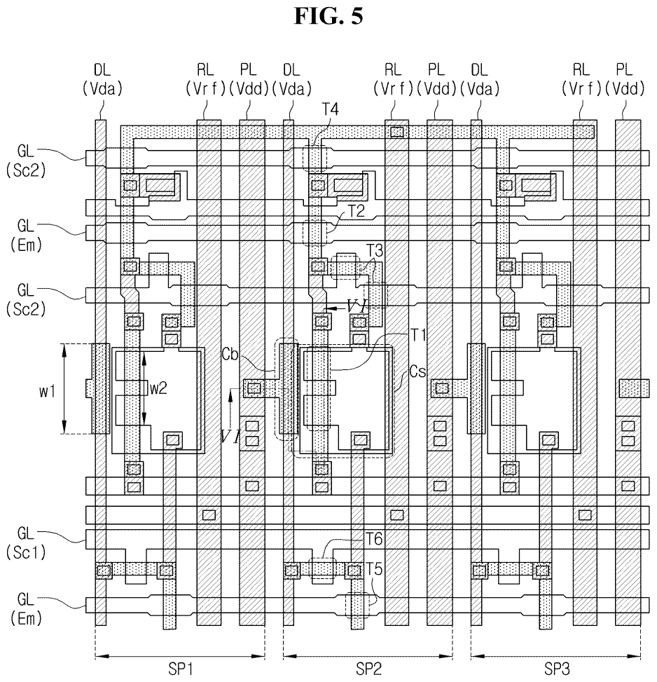

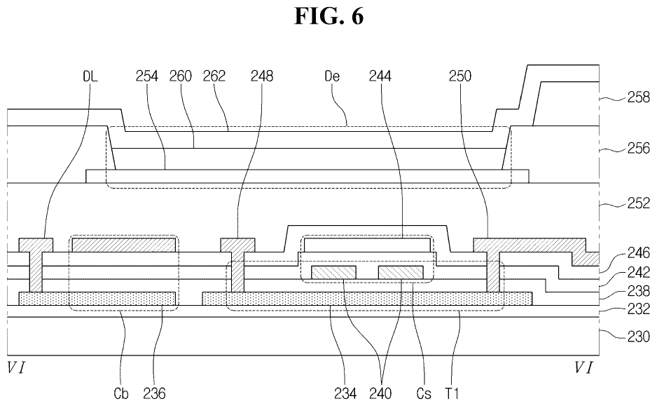

FIG. 5 is a plan view showing first, second, and third subpixels of a display device according to a second example embodiment of the present disclosure, and FIG. 6 is a cross-sectional view taken along a line VI-VI′ in FIG. 5.

In FIG. 5, each of first, second, and third subpixels SP1, SP2, and SP3 of a display device according to a second example embodiment of the present disclosure includes gate lines GL, a data line DL, a reference line RL, and a power line PL. The gate line GL transmitting a scan2 signal Sc2, the gate line GL transmitting an emission signal Em, the gate line GL transmitting the scan2 signal Sc2, and the gate line GL transmitting a scan1 signal Sc1 are sequentially disposed along a horizontal direction. The data line DL transmitting a data signal Vda, the reference line RL transmitting a reference signal Vrf, and the power line PL transmitting a high level signal Vdd are sequentially disposed along a vertical direction.

A first transistor T1 is connected to the power line PL transmitting the high level signal, and a second transistor T2 is connected to the gate line GL transmitting the emission signal Em. A third transistor T3 is connected to the gate line GL transmitting the scan2 signal Sc2, and a fourth transistor T4 is connected to the gate line GL transmitting the scan2 signal Sc2 and the reference line RL transmitting the reference signal Vrf. A fifth transistor T5 is connected to the gate line GL transmitting the emission signal Em and the reference line RL transmitting the reference signal Vrf, and a sixth transistor T6 is connected to the gate line GL transmitting the scan1 signal Sc1 and the data line DL transmitting the data signal Vda.

A metal pattern 244 (of FIG. 6) is disposed on a gate electrode 240 (of FIG. 6) of the first transistor T1, and the gate electrode 240 of the first transistor T1 and the metal pattern 244 constitute a storage capacitor Cs.

A shielding pattern 236 (of FIG. 6) connected to the power line PL is disposed under the data line DL adjacent to the first transistor T1, and the shielding pattern 236 and the data line DL constitute a shielding capacitor Cb.

Since the shielding pattern 236 is disposed closer to the data line DL than the gate electrode 240 of the first transistor T1, most of electric field lines of the data line DL do not reach the gate electrode 240 of the first transistor T1 but reaches the shielding pattern 236. As a result, a coupling (or parasitic capacitance) between the data line DL and the gate electrode 240 (i.e., first node N1) of the first transistor T1 is reduced, a voltage change of the gate electrode 240 of the first transistor T1 can be minimized or reduced, and deterioration such as a vertical crosstalk can be prevented or suppressed.

Accordingly, the shielding pattern 236 is formed to correspond to a whole of an end portion of the gate electrode 240 of the adjacent first transistor T1.

For example, a first width w1 of the shielding pattern 236 may be greater than a second width w2 of the gate electrode 240 of the first transistor T1.

In FIG. 6, a buffer layer 232 is disposed on an entire substrate 230, and a semiconductor layer 234 and a shielding pattern 236 are disposed on the buffer layer 232.

The buffer layer 232 blocks a moisture or an oxygen permeating from an exterior. For example, the buffer layer 232 may have a single layer or a multiple layer of an inorganic insulating material, such as silicon oxide (SiO₂) and silicon nitride (SiNx).

The semiconductor layer 234 includes a channel region not doped with an impurity at a central portion thereof and source and drain regions doped with an impurity at both side portions of the channel region. For example, the semiconductor layer 234 may include a polycrystalline semiconductor material, such as polycrystalline silicon, or an oxide semiconductor material, such as indium gallium zinc oxide (IGZO), zinc oxide (ZnO), tin oxide (SnO₂), copper oxide (Cu₂O), nickel oxide (NiO), indium tin zinc oxide (ITZO), and indium aluminum zinc oxide (IAZO).

The shielding pattern 236 is separated from the semiconductor layer 234 and is doped with an impurity. For example, the shielding pattern 236 may include a polycrystalline semiconductor material, such as polycrystalline silicon, or an oxide semiconductor material, such as indium gallium zinc oxide (IGZO), zinc oxide (ZnO), tin oxide (SnO₂), copper oxide (Cu₂O), nickel oxide (NiO), indium tin zinc oxide (ITZO), and indium aluminum zinc oxide (IAZO).

A gate insulating layer 238 is disposed on the semiconductor layer 234 and the shielding pattern 236 over the entire substrate 230, and a gate electrode 240 is disposed on the gate insulating layer 238 corresponding to the channel region of the semiconductor layer 234.

For example, the gate insulating layer 238 may have a single layer or a multiple layer of an inorganic insulating material, such as silicon oxide (SiO₂) and silicon nitride (SiNx).

For example, the gate electrode 240 may have a single layer or a multiple layer of a metallic material, such as molybdenum (Mo), aluminum (Al), chromium (Cr), gold (Au), titanium (Ti), nickel (Ni), neodymium (Nd), copper (Cu), and an alloy thereof.

The semiconductor layer 234, the gate insulating layer 238 and the gate electrode 240 constitute the first transistor T1.

Although the first transistor T1 exemplarily has a dual gate type including two gate electrodes and two channel regions separated from each other in a plan view in the second example embodiment of FIGS. 5 and 6, the first transistor T1 may have a single gate type including one gate electrode and one channel region in another embodiment.

A first interlayer insulating layer 242 is disposed on the gate electrode 240 over the entire substrate 230, and a metal pattern 244 is disposed on the first interlayer insulating layer 242 corresponding to the gate electrode 240.

For example, the first interlayer insulating layer 242 may have a single layer or a multiple layer of an inorganic insulating material, such as silicon oxide (SiO₂) and silicon nitride (SiNx).

For example, the metal pattern 244 may have a single layer or a multiple layer of a metallic material, such as molybdenum (Mo), aluminum (Al), chromium (Cr), gold (Au), titanium (Ti), nickel (Ni), neodymium (Nd), copper (Cu), and an alloy thereof.

The gate electrode 240, the first interlayer insulating layer 242, and the metal pattern 244 constitute the storage capacitor Cs, and the gate electrode 240 and the metal pattern 244 function as first and second capacitor electrodes, respectively, of the storage capacitor Cs.

A second interlayer insulating layer 246 is disposed on the metal pattern 244 over the entire substrate 230, and a source electrode 248, a drain electrode 250, the data line DL, and the power line PL are disposed on the second interlayer insulating layer 246.

For example, the second interlayer insulating layer 246 may have a single layer or a multiple layer of an inorganic insulating material, such as silicon oxide (SiO₂) and silicon nitride (SiNx).

The source electrode 248 and the drain electrode 250 are connected to the source region and the drain region, respectively, of the semiconductor layer 234 through contact holes in the second interlayer insulating layer 246, the first interlayer insulating layer 242 and the gate insulating layer 238.

The data line DL is disposed to overlap the shielding pattern 236.

The power line PL is connected to the shielding pattern 236 through a contact hole in the second interlayer insulating layer 246, the first interlayer insulating layer 242, and the gate insulating layer 238.

For example, the source electrode 248, the drain electrode 250, the data line DL, and the power line PL may have a single layer or a multiple layer of a metallic material, such as molybdenum (Mo), aluminum (Al), chromium (Cr), gold (Au), titanium (Ti), nickel (Ni), neodymium (Nd), copper (Cu), and an alloy thereof.

The shielding pattern 236, the gate insulating layer 238, the first interlayer insulating layer 242, the second interlayer insulating layer 246 and the data line DL constitute the shielding capacitor Cb, and the shielding pattern 236 and the data line DL function as first and second capacitor electrodes, respectively, of the shielding capacitor Cb.

A planarizing layer 252 is disposed on the source electrode 248, the drain electrode 250, the data line DL, and the power line PL over the entire substrate 230, and a first electrode 254 is disposed on the planarizing layer 252.

For example, the planarizing layer 252 may have a single layer or a multiple layer of an organic insulating material, such as photoacryl and benzocyclobutene (BCB).

The first electrode 254 may be connected to a drain region of the second transistor T2 or a source region of the fourth transistor T4 through a contact hole in the planarizing layer 252.

For example, the first electrode 254 may be an anode and may have a single layer or a multiple layer of a transparent conductive material, such as indium tin oxide (ITO) and indium zinc oxide (IZO) or an opaque metallic material such as aluminum (Al), silver (Ag), copper (Cu), lead (Pb), molybdenum (Mo), titanium (Ti), and an alloy thereof.

A bank layer 256 is disposed on the first electrode 254, and a spacer 258 is disposed on the bank layer 256.

The bank layer 256 covers an edge portion of the first electrode 254 and has an opening exposing a central portion of the first electrode 254.

For example, the bank layer 256 may have a single layer or a multiple layer of an organic insulating material, such as photoacryl and benzocyclobutene (BCB).

For example, the spacer 258 may have a single layer or a multiple layer of an organic insulating material, such as photoacryl and benzocyclobutene (BCB).

An emitting layer 260 may be disposed on the first electrode 254 exposed through the opening of the bank layer 256, and a second electrode 262 is disposed on the emitting layer 260 over the entire substrate 230.

The emitting layer 260 may include a hole assisting layer such as a hole injecting layer and a hole transporting layer, an emitting material layer, and an electron assisting layer such as an electron transporting layer and an electron injecting layer.

For example, the second electrode 262 may be a cathode and may have a single layer or a multiple layer of a transparent conductive material, such as indium tin oxide (ITO) and indium zinc oxide (IZO), or a half-transmissive material or an opaque metallic material, such as aluminum (Al), silver (Ag), copper (Cu), lead (Pb), magnesium (Mg), molybdenum (Mo), titanium (Ti), and an alloy thereof.

The first electrode 254, the emitting layer 260 and the second electrode 262 constitute the light emitting diode De.

Although not shown, an encapsulating layer may be disposed on the second electrode 262 over the entire substrate 230. For example, the encapsulating layer may include first and third encapsulating layers having a single layer or a multiple layer of an inorganic insulating material, such as silicon oxide (SiO₂) and silicon nitride (SiNx), and a second encapsulating layer between the first and third encapsulating layers and including an organic insulating material, such as acryl resin, epoxy resin, phenolic resin, polyamide resin, and polyimide resin.

A touch layer for sensing a touch may be disposed on the encapsulating layer.

In the display device according to a second example embodiment of the present disclosure, the shielding pattern 236 connected to the power line PL is disposed under the data line DL adjacent to the gate electrode 240 of the first transistor T1 to constitute the shielding capacitor Cb having the shielding pattern 236 and the data line DL. As a result, a coupling (or parasitic capacitance) between the data line DL and the gate electrode 240 of the first transistor T1 (between the data line DL and the first node N1) can be reduced, a voltage change of the gate electrode 240 of the first transistor T1 can be minimized or reduced, and deterioration such as a vertical crosstalk can be prevented or suppressed.

In another embodiment, the shielding pattern may extend from the drain region of the semiconductor layer.

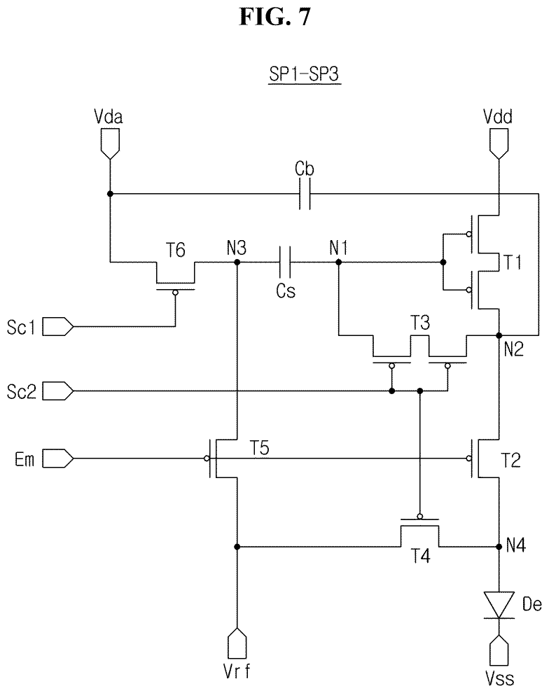

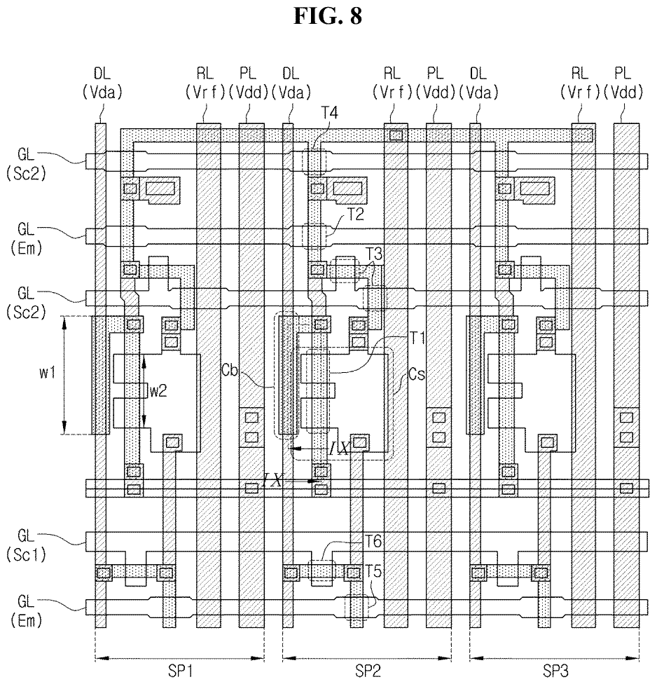

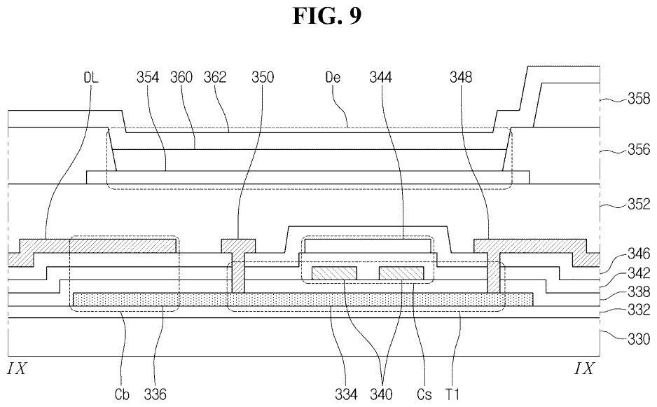

FIG. 7 is a circuit diagram showing a subpixel of a display device according to a third example embodiment of the present disclosure, FIG. 8 is a plan view showing first, second, and third subpixels of a display device according to a third example embodiment of the present disclosure, and FIG. 9 is a cross-sectional view taken along a line IX-IX′ in FIG. 8. Illustration on a part the same as that of the first and second example embodiments will be omitted.

In FIG. 7, each of the first, second, and third subpixels SP1, SP2, and SP3 of a display device according to a third example embodiment of the present disclosure includes first to sixth transistors T1 to T6, a storage capacitor Cs, a shielding capacitor Cb, and a light emitting diode De.

The first transistor T1 as a driving transistor is switched according to a voltage of a first node N1. A gate electrode of the first transistor T1 is connected to the first node N1, a source electrode of the first transistor T1 is connected to a high level signal (high level voltage) Vdd, and a drain electrode of the first transistor T1 is connected to a second node N2.

The second transistor T2 as an emitting transistor is switched according to an emission signal Em. A gate electrode of the second transistor T2 is connected to the emission signal Em, a source electrode of the second transistor T2 is connected to the second node N2, and a drain electrode of the second transistor T2 is connected to a fourth node N4.

The third transistor T3 as a sensing transistor is switched according to a scan2 signal Sc2. A gate electrode of the third transistor T3 is connected to the scan2 signal Sc2, a source electrode of the third transistor T3 is connected to the second node N2, and a drain electrode of the third transistor T3 is connected to the first node N1.

The fourth transistor T4 is switched according to the scan2 signal Sc2. A gate electrode of the fourth transistor T4 is connected to the scan2 signal Sc2, a source electrode of the fourth transistor T4 is connected to the fourth node N4, and a drain electrode of the fourth transistor T4 is connected to a reference signal (reference voltage) Vrf.

The fifth transistor T5 switched according to the emission signal Em. A gate electrode of the fifth transistor T5 is connected to the emission signal Em, a source electrode of the fifth transistor T5 is connected to the third node N3, and a drain electrode of the fifth transistor T5 is connected to the reference signal Vrf.

The sixth transistor T6 as a switching transistor is switched according to a scan1 signal Sc1. A gate electrode of the sixth transistor T6 is connected to the scan1 signal Sc1, a source electrode of the sixth transistor T6 is connected to the third node N3, and a drain electrode of the sixth transistor T6 is connected to a data signal Vda.

The storage capacitor Cs stores the data signal Vda and a threshold voltage (Vth) of the first transistor T1. A first capacitor electrode of the storage capacitor Cs is connected to the first node N1, and a second capacitor electrode of the storage capacitor Cs is connected to the third node N3.

The shielding capacitor Cb reduces a coupling between the data line DL and the first node N1. A first capacitor electrode of the shielding capacitor Cb is connected to the second node N2, and a second capacitor electrode of the shielding capacitor Cb is connected to the data signal Vda.

The light emitting diode De is connected between the fourth node N4 and a low level signal (low level voltage) Vss and emits a light of a luminance proportional to a current of the first transistor T1. An anode of the light emitting diode De is connected to the fourth node N4, and a cathode of the light emitting diode De is connected to the low level signal Vss.

The gate electrode of the first transistor T1, the first capacitor electrode of the storage capacitor Cs, and the drain electrode of the third transistor T3 constitute the first node N1, and the drain electrode of the first transistor T1, the source electrode of the second transistor T2, and the source electrode of the third transistor T3 constitute the second node N2. The second capacitor electrode of the storage capacitor Cs, the source electrode of the fifth transistor T5, and the source electrode of the sixth transistor T6 constitute the third node N3, and the drain electrode of the second transistor T2, the source electrode of the fourth transistor T4, and the anode of the light emitting diode De constitute the fourth node N4.

Each of the first, second, and third subpixels SP1, SP2, and SP3 of the display device according to a third example embodiment of the present disclosure is driven through an initializing period, a sampling period, a holding period and an emitting period.

In FIG. 8, each of first, second, and third subpixels SP1, SP2, and SP3 of a display device according to a third example embodiment of the present disclosure includes gate lines GL, a data line DL, a reference line RL, and a power line PL. The gate line GL transmitting a scan2 signal Sc2, the gate line GL transmitting an emission signal Em, the gate line GL transmitting the scan2 signal Sc2, and the gate line GL transmitting a scan1 signal Sc1 are sequentially disposed along a horizontal direction. The data line DL transmitting a data signal Vda, the reference line RL transmitting a reference signal Vrf, and the power line PL transmitting a high level signal Vdd are sequentially disposed along a vertical direction.

A first transistor T1 is connected to the power line PL transmitting the high level signal, and a second transistor T2 is connected to the gate line GL transmitting the emission signal Em. A third transistor T3 is connected to the gate line GL transmitting the scan2 signal Sc2, and a fourth transistor T4 is connected to the gate line GL transmitting the scan2 signal Sc2 and the reference line RL transmitting the reference signal Vrf. A fifth transistor T5 is connected to the gate line GL transmitting the emission signal Em and the reference line RL transmitting the reference signal Vrf, and a sixth transistor T6 is connected to the gate line GL transmitting the scan1 signal Sc1 and the data line DL transmitting the data signal Vda.

A metal pattern 344 (of FIG. 9) is disposed on a gate electrode 340 (of FIG. 9) of the first transistor T1, and the gate electrode 340 of the first transistor T1 and the metal pattern 344 constitute a storage capacitor Cs.

A shielding pattern 336 (of FIG. 9) extending from a drain region of a semiconductor layer 334 (of FIG. 9) of the first transistor T1 is disposed under the data line DL adjacent to the first transistor T1, and the shielding pattern 336 and the data line DL constitute a shielding capacitor Cb.

Since the shielding pattern 336 is disposed closer to the data line DL than the gate electrode 340 of the first transistor T1, most of electric field lines of the data line DL do not reach the gate electrode 340 of the first transistor T1 but reaches the shielding pattern 336. As a result, a coupling (or parasitic capacitance) between the data line DL and the gate electrode 340 (i.e., first node N1) of the first transistor T1 can be reduced, a voltage change of the gate electrode 340 of the first transistor T1 can be minimized or reduced, and deterioration such as a vertical crosstalk can be prevented or suppressed.

Accordingly, the shielding pattern 336 is formed to correspond to a whole of an end portion of the gate electrode 340 of the adjacent first transistor T1.

For example, a first width w1 of the shielding pattern 336 may be greater than a second width w2 of the gate electrode 340 of the first transistor T1.

In FIG. 9, a buffer layer 332 is disposed on an entire substrate 330, and a semiconductor layer 334 and a shielding pattern 336 are disposed on the buffer layer 332.

The buffer layer 332 blocks a moisture or an oxygen permeating from an exterior. For example, the buffer layer 332 may have a single layer or a multiple layer of an inorganic insulating material, such as silicon oxide (SiO₂) and silicon nitride (SiNx).

The semiconductor layer 334 includes a channel region not doped with an impurity at a central portion thereof and source and drain regions doped with an impurity at both side portions of the channel region. For example, the semiconductor layer 334 may include a polycrystalline semiconductor material, such as polycrystalline silicon, or an oxide semiconductor material, such as indium gallium zinc oxide (IGZO), zinc oxide (ZnO), tin oxide (SnO₂), copper oxide (Cu₂O), nickel oxide (NiO), indium tin zinc oxide (ITZO), and indium aluminum zinc oxide (IAZO).

The shielding pattern 336 extends from the drain region of the semiconductor layer 334 and is doped with an impurity. For example, the shielding pattern 336 may include a polycrystalline semiconductor material, such as polycrystalline silicon, or an oxide semiconductor material, such as indium gallium zinc oxide (IGZO), zinc oxide (ZnO), tin oxide (SnO₂), copper oxide (Cu₂O), nickel oxide (NiO), indium tin zinc oxide (ITZO), and indium aluminum zinc oxide (IAZO).

A gate insulating layer 338 is disposed on the semiconductor layer 334 and the shielding pattern 336 over the entire substrate 330, and a gate electrode 340 is disposed on the gate insulating layer 338 corresponding to the channel region of the semiconductor layer 334.

For example, the gate insulating layer 338 may have a single layer or a multiple layer of an inorganic insulating material, such as silicon oxide (SiO₂) and silicon nitride (SiNx).

For example, the gate electrode 340 may have a single layer or a multiple layer of a metallic material, such as molybdenum (Mo), aluminum (Al), chromium (Cr), gold (Au), titanium (Ti), nickel (Ni), neodymium (Nd), copper (Cu), and an alloy thereof.

The semiconductor layer 334, the gate insulating layer 338 and the gate electrode 340 constitute the first transistor T1.

Although the first transistor T1 exemplarily has a dual gate type including two gate electrodes and two channel regions separated from each other in a plan view in the third example embodiment of FIGS. 8 and 9, the first transistor T1 may have a single gate type including one gate electrode and one channel region in another embodiment.

A first interlayer insulating layer 342 is disposed on the gate electrode 340 over the entire substrate 330, and a metal pattern 344 is disposed on the first interlayer insulating layer 342 corresponding to the gate electrode 340.

For example, the first interlayer insulating layer 342 may have a single layer or a multiple layer of an inorganic insulating material, such as silicon oxide (SiO₂) and silicon nitride (SiNx).

For example, the metal pattern 344 may have a single layer or a multiple layer of a metallic material, such as molybdenum (Mo), aluminum (Al), chromium (Cr), gold (Au), titanium (Ti), nickel (Ni), neodymium (Nd), copper (Cu), and an alloy thereof.

The gate electrode 340, the first interlayer insulating layer 342, and the metal pattern 344 constitute the storage capacitor Cs, and the gate electrode 340 and the metal pattern 344 function as first and second capacitor electrodes, respectively, of the storage capacitor Cs.

A second interlayer insulating layer 346 is disposed on the metal pattern 344 over the entire substrate 330, and a source electrode 348, a drain electrode 350, and the data line DL are disposed on the second interlayer insulating layer 346.

For example, the second interlayer insulating layer 346 may have a single layer or a multiple layer of an inorganic insulating material, such as silicon oxide (SiO₂) and silicon nitride (SiNx).

The source electrode 348 and the drain electrode 350 are connected to the source region and the drain region, respectively, of the semiconductor layer 334 through contact holes in the second interlayer insulating layer 346, the first interlayer insulating layer 342, and the gate insulating layer 338.

The data line DL is disposed to overlap the shielding pattern 336.

For example, the source electrode 348, the drain electrode 350, and the data line DL may have a single layer or a multiple layer of a metallic material, such as molybdenum (Mo), aluminum (Al), chromium (Cr), gold (Au), titanium (Ti), nickel (Ni), neodymium (Nd), copper (Cu), and an alloy thereof.

The shielding pattern 336, the gate insulating layer 338, the first interlayer insulating layer 342, the second interlayer insulating layer 346, and the data line DL constitute the shielding capacitor Cb, and the shielding pattern 336 and the data line DL function as first and second capacitor electrodes, respectively, of the shielding capacitor Cb.

A planarizing layer 352 is disposed on the source electrode 348, the drain electrode 350, and the data line DL over the entire substrate 330, and a first electrode 354 is disposed on the planarizing layer 352.

For example, the planarizing layer 352 may have a single layer or a multiple layer of an organic insulating material, such as photoacryl and benzocyclobutene (BCB).

The first electrode 354 may be connected to a drain region of the second transistor T2 or a source region of the fourth transistor T4 through a contact hole in the planarizing layer 352.

For example, the first electrode 354 may be an anode and may have a single layer or a multiple layer of a transparent conductive material, such as indium tin oxide (ITO) and indium zinc oxide (IZO), or an opaque metallic material, such as aluminum (Al), silver (Ag), copper (Cu), lead (Pb), molybdenum (Mo), titanium (Ti), and an alloy thereof.

A bank layer 356 is disposed on the first electrode 354, and a spacer 358 is disposed on the bank layer 356.

The bank layer 356 covers an edge portion of the first electrode 354 and has an opening exposing a central portion of the first electrode 354.

For example, the bank layer 356 may have a single layer or a multiple layer of an organic insulating material, such as photoacryl and benzocyclobutene (BCB).

For example, the spacer 358 may have a single layer or a multiple layer of an organic insulating material, such as photoacryl and benzocyclobutene (BCB).

An emitting layer 360 may be disposed on the first electrode 354 exposed through the opening of the bank layer 356, and a second electrode 362 is disposed on the emitting layer 360 over the entire substrate 330.

The emitting layer 360 may include a hole assisting layer such as a hole injecting layer and a hole transporting layer, an emitting material layer, and an electron assisting layer such as an electron transporting layer and an electron injecting layer.

For example, the second electrode 362 may be a cathode and may have a single layer or a multiple layer of a transparent conductive material, such as indium tin oxide (ITO) and indium zinc oxide (IZO), or a half-transmissive material or an opaque metallic material, such as aluminum (Al), silver (Ag), copper (Cu), lead (Pb), magnesium (Mg), molybdenum (Mo), titanium (Ti), and an alloy thereof.

The first electrode 354, the emitting layer 360, and the second electrode 362 constitute the light emitting diode De.

Although not shown, an encapsulating layer may be disposed on the second electrode 362 over the entire substrate 330. For example, the encapsulating layer may include first and third encapsulating layers having a single layer or a multiple layer of an inorganic insulating material, such as silicon oxide (SiO₂) and silicon nitride (SiNx), and a second encapsulating layer between the first and third encapsulating layers and including an organic insulating material, such as acryl resin, epoxy resin, phenolic resin, polyamide resin, and polyimide resin.

A touch layer for sensing a touch may be disposed on the encapsulating layer.

In the display device according to a third example embodiment of the present disclosure, the shielding pattern 336 extending from the drain region of the semiconductor layer 334 of the first transistor T1 is disposed under the data line DL adjacent to the gate electrode 340 of the first transistor T1 to constitute the shielding capacitor Cb having the shielding pattern 336 and the data line DL. As a result, a coupling (or parasitic capacitance) between the data line DL and the gate electrode 340 of the first transistor T1 (between the data line DL and the first node N1) can be reduced, a voltage change of the gate electrode 340 of the first transistor T1 can be minimized or reduced, and deterioration such as a vertical crosstalk can be prevented or suppressed. Accordingly, the display device can be driven with a relatively low power consumption.

It will be apparent to those skilled in the art that various modifications and variation may be made in the present disclosure without departing from the scope of the disclosure. Thus, it is intended that the present disclosure cover the modifications and variations of this disclosure provided they come within the scope of the appended claims and their equivalents.

What is claimed is:

1. A display device, comprising:
a display panel including a display area having a plurality of subpixels and a non-display area at a periphery of the display area;
a storage capacitor and a first transistor in each of the plurality of subpixels;
a data line disposed adjacent to a gate electrode of the first transistor; and
a shielding capacitor disposed to overlap the data line,
wherein a first width of the shielding capacitor is greater than a second width of the gate electrode of the first transistor.

2. The display device of claim 1, wherein the first transistor comprises:
a semiconductor layer on a substrate and including a channel region at a central portion thereof and a source region and a drain region respectively at opposing side portions of the channel region;
a gate insulating layer on the semiconductor layer; and
the gate electrode on the gate insulating layer corresponding to the semiconductor layer.

3. The display device of claim 2, wherein the shielding capacitor comprises:
a shielding pattern on the substrate;
the gate insulating layer, a first interlayer insulating layer, and a second interlayer insulating layer sequentially on the shielding pattern; and
the data line on the second interlayer insulating layer corresponding to the shielding pattern.

4. The display device of claim 3, wherein the shielding pattern extends from the source region of the semiconductor layer of the first transistor.

5. The display device of claim 3, wherein the shielding pattern is separated from the semiconductor layer of the first transistor and transmits a high level signal through a contact hole in the gate insulating layer, the first interlayer insulating layer, and the second interlayer insulating layer.

6. The display device of claim 3, wherein the shielding pattern extends from the drain region of the semiconductor layer of the first transistor.

7. The display device of claim 3, wherein the storage capacitor comprises:
the gate electrode of the first transistor;
the first interlayer insulating layer on the gate electrode of the first transistor; and
a metal pattern on the first interlayer insulating layer.

8. The display device of claim 1, further comprising:
a plurality of gate lines transmitting a first scan signal, a second scan signal, and an emission signal and sequentially disposed along a horizontal direction in the display area; and
a reference line and a power line disposed along a vertical direction in the display area.

9. The display device of claim 1, wherein the first transistor has a dual gate type including two gate electrodes and two channel regions separated from each other in a plan view.

10. The display device of claim 9, wherein the second width is a width of the two gate electrodes.

11. The display device of claim 1, further comprising a light emitting diode on the first transistor and the shielding capacitor.

12. The display device of claim 3, wherein the shielding pattern is disposed closer to the data line than the gate electrode of the first transistor.

13. The display device of claim 12, wherein the shielding pattern is doped with an impurity.

14. The display device of claim 5, wherein the shielding pattern is connected to a power line.

15. The display device of claim 1, wherein the first transistor is configured as a driving transistor.
